(19) United States
(12) Patent Application Publication
(10) Pub. No.: US 2023/0163747 A1
(43) Pub. Date: May 25, 2023

(54) ACOUSTIC WAVE DEVICE

(71) Applicant: Murata Manufacturing Co., Ltd., Nagaokakyo-shi (JP)

(72) Inventor: Sho NAGATOMO, Nagaokakyo-shi (JP)

(21) Appl. No.: 18/099,344

(22) Filed: Jan. 20, 2023

Related U.S. Application Data
(63) Continuation of application No. PCT/JP2021/026162, filed on Jul. 12, 2021.

(51) Int. Cl. H03H 9/02; H03H 9/13; H03H 9/17

(52) U.S. Cl. CPC H03H 9/02574; H03H 9/131; H03H 9/173; H03H 9/02007; H03H 9/02559; H03H 9/02992

(57) ABSTRACT

An acoustic wave device includes a piezoelectric layer made of lithium niobate or lithium tantalate and including a first main surface, and an IDT electrode and a first dielectric film on the first main surface. A ratio d/p is equal to or less than about 0.5, when a thickness of the piezoelectric layer is d and a center-to-center distance between adjacent electrodes is p. The first dielectric film includes first and second surfaces facing each other. The second surface is a surface on a side of the piezoelectric layer. The IDT electrode includes third and fourth surfaces facing each other. The fourth surfaces are on the side of the piezoelectric layer. The first surface of the first dielectric film is at a same height as or higher than the third surfaces of the IDT electrode. A second dielectric film is on the first surface of the first dielectric film.

### CROSS REFERENCE TO RELATED APPLICATIONS

This application claims the benefit of priority to Provisional Patent Application No. 63/054,818 filed on Jul. 22, 2020 and is a Continuation Application of PCT Application No. PCT/JP2021/026162 filed on Jul. 12, 2021. The entire contents of each application are hereby incorporated herein by reference.

### BACKGROUND OF THE INVENTION

### 1. Field of the Invention

The present invention relates to an acoustic wave device.

### 2. Description of the Related Art

In the past, acoustic wave devices have been widely used in filters of mobile phones, and the like. In recent years, an acoustic wave device has been proposed in which a bulk wave in a thickness shear mode is used as described in U.S. Pat. No. 10,491,192 below. In this acoustic wave device, electrodes to form a pair are provided on a piezoelectric layer. The electrodes to form the pair face each other on the piezoelectric layer, and are connected to potentials different from each other. An AC voltage is applied between the electrodes to excite a bulk wave in a thickness shear mode.

### SUMMARY OF THE INVENTION

When the bulk wave in the thickness shear mode is utilized, a response of an unnecessary wave is likely to occur. Thus, there is a possibility that electrical characteristics of the acoustic wave device deteriorate.

Preferred embodiments of the present invention provide acoustic wave devices each capable of reducing or preventing the response of unnecessary waves.

An acoustic wave device according to a preferred embodiment of the present invention includes a piezoelectric layer made of one of lithium niobate and lithium tantalate, and including a main surface, at least one pair of electrodes on the main surface of the piezoelectric layer, and a first dielectric film on the main surface of the piezoelectric layer, in which a ratio d/p is equal to or less than about 0.5, when a thickness of the piezoelectric layer is d and a center-to-center distance between the electrodes adjacent to each other is p, the first dielectric film includes a first surface and a second surface facing each other in a thickness direction, the second surface is a surface on a side of the piezoelectric layer, the at least one pair of electrodes each include a third surface and a fourth surface facing each other in the thickness direction, the fourth surface is a surface on a side of the piezoelectric layer, the first surface of the first dielectric film is at a same height or higher than the third surface of the at least one pair of electrodes, and a second dielectric film is on the first surface of the first dielectric film.

According to preferred embodiments of the present invention, it is possible to provide acoustic wave devices each capable of reducing or preventing a response of unnecessary waves.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a plan view of an acoustic wave device according to a first preferred embodiment of the present invention.

FIG. 2 is a cross-sectional view taken along a line I-I in FIG. 1.

FIG. 3 is a front cross-sectional view, of an acoustic wave device according to a first modification example of the first preferred embodiment of the present invention, illustrating a vicinity of one pair of electrode fingers.

FIG. 4 is a graph, of a comparative example, showing impedance-frequency characteristics when w/p is about 0.3.

FIG. 5 is a graph, of the comparative example, showing impedance-frequency characteristics when w/p is about 0.4.

FIG. 6 is a graph, of the comparative example, showing impedance-frequency characteristics when w/p is about 0.5.

FIG. 7 is a graph, of the first modification example of the first preferred embodiment of the present invention, showing impedance-frequency characteristics when w/p is about 0.3.

FIG. 8 is a graph, of the first modification example of the first preferred embodiment of the present invention, showing impedance-frequency characteristics when w/p is about 0.4.

FIG. 9 is a graph, of the first modification example of the first preferred embodiment of the present invention, showing impedance-frequency characteristics when w/p is about 0.5.

FIG. 10 is a graph, of the comparative example, showing impedance-frequency characteristics when an electrode finger is made of Al.

FIG. 11 is a graph, of the first modification example of the first preferred embodiment of the present invention, showing impedance-frequency characteristics when the electrode finger is made of Al, and pd1/pe is about 0.4.

FIG. 12 is a graph, of the first modification example of the first preferred embodiment of the present invention, showing impedance-frequency characteristics when the electrode finger is made of Al, and pd1/pe is about 0.6.

FIG. 13 is a graph, of the first modification example of the first preferred embodiment of the present invention, showing impedance-frequency characteristics when the electrode finger is made of Al, and pd1/pe is about 0.8.

FIG. 14 is a graph, of the comparative example, showing impedance-frequency characteristics when the electrode finger is made of Cu.

FIG. 15 is a graph, of the first modification example of the first preferred embodiment of the present invention, showing impedance-frequency characteristics when the electrode finger is made of Cu, and pd1/pe is about 0.4.

FIG. 16 is a graph, of the first modification example of the first preferred embodiment of the present invention, showing impedance-frequency characteristics when the electrode finger is made of Cu, and pd1/pe is about 0.6.

FIG. 17 is a graph, of the first modification example of the first preferred embodiment of the present invention, showing impedance-frequency characteristics when the electrode finger is made of Cu, and pd1/pe is about 0.8.

FIG. 18 is a graph, of the first modification example of the first preferred embodiment of the present invention, showing impedance-frequency characteristics when p/d is about 4.

FIG. 19 is a graph, of the first modification example of the first preferred embodiment of the present invention, showing impedance-frequency characteristics when p/d is about 5.

FIG. 20 is a graph, of the first modification example of the first preferred embodiment of the present invention, showing impedance-frequency characteristics when p/d is about 6.

FIG. 21 is a graph, of the first modification example of the first preferred embodiment of the present invention, showing impedance-frequency characteristics when p/d is about 7.

FIG. 22 is a front cross-sectional view, of an acoustic wave device according to a second modification example of the first preferred embodiment of the present invention, illustrating a vicinity of one pair of electrode fingers.

FIG. 23 is a front cross-sectional view, of an acoustic wave device according to a second preferred embodiment of the present invention, illustrating a vicinity of one pair of electrode fingers.

FIG. 24 is a graph showing impedance-frequency characteristics in the first preferred embodiment and the second preferred embodiment of the present invention.

FIG. 25 is a graph showing a relationship between thickness ratio (h/td1) × 100[%] and fractional bandwidth.

FIG. 26 is a front cross-sectional view, of an acoustic wave device according to a third preferred embodiment of the present invention, illustrating a vicinity of one pair of electrode fingers.

FIG. 27 is a front cross-sectional view, of an acoustic wave device according to a fourth preferred embodiment of the present invention, illustrating a vicinity of one pair of electrode fingers.

FIG. 28A is a schematic perspective view illustrating an external appearance of an acoustic wave device in which a bulk wave in a thickness shear mode is utilized, and FIG. 28B is a plan view illustrating electrode structure on a piezoelectric layer.

FIG. 29 is a cross-sectional view of a portion taken along a line A-A in FIG. 28A.

FIG. 30A is a schematic front cross-sectional view for explaining a Lamb wave propagating through a piezoelectric film of an acoustic wave device, and FIG. 30B is a schematic front cross-sectional view for explaining a bulk wave in a thickness shear mode propagating through the piezoelectric film in the acoustic wave device.

FIG. 31 is a diagram illustrating an amplitude direction of the bulk wave in the thickness shear mode.

FIG. 32 is a diagram showing resonance characteristics of the acoustic wave device in which the bulk wave in the thickness shear mode is utilized.

FIG. 33 is a graph showing a relationship between d/2p and fractional bandwidth as a resonator, when a center-to-center distance between adjacent electrodes is p, and a thickness of a piezoelectric layer is d.

FIG. 34 is a plan view of an acoustic wave device in which the bulk wave in the thickness shear mode is utilized.

FIG. 35 is a front cross-sectional view of an acoustic wave device having an acoustic multilayer film.

FIG. 36 is a graph showing a map of fractional bandwidth with respect to Euler angles (0°, θ, ψ) of LiNbO₃ when d/p is made as close to 0 as possible.

### DETAILED DESCRIPTION OF THE PREFERRED EMBODIMENTS

Hereinafter, specific preferred embodiments of the present invention will be described with reference to the figures to clarify the present invention.

Note that, each of the preferred embodiments described in the present specification is illustrative, and partial replacement or combination of configurations is possible between different preferred embodiments.

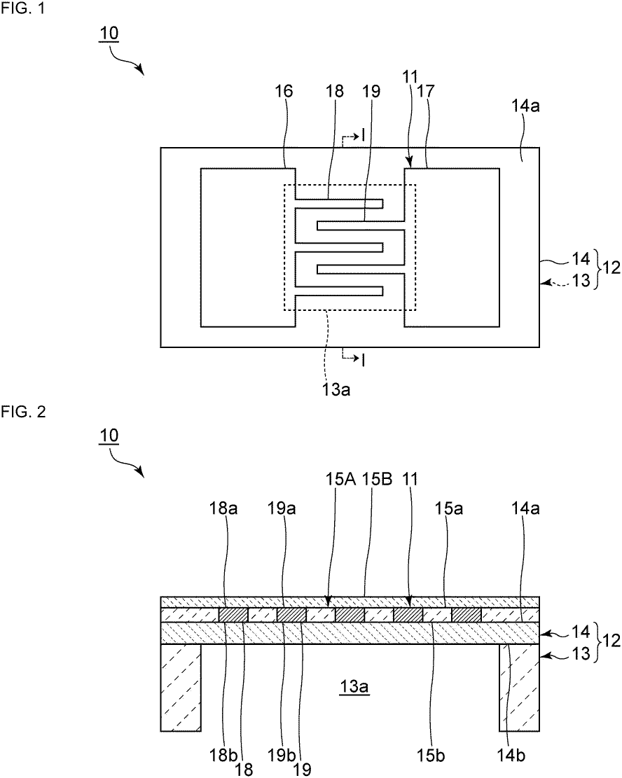

FIG. 1 is a plan view of an acoustic wave device according to a first preferred embodiment of the present invention. FIG. 2 is a cross-sectional view taken along a line I-I in FIG. 1.

As illustrated in FIG. 1, an acoustic wave device 10 includes a piezoelectric substrate 12, and a functional electrode. The piezoelectric substrate 12 is a laminated substrate including a piezoelectric layer 14. In the present preferred embodiment, the functional electrode is an IDT electrode 11.

As illustrated in FIG. 2, the piezoelectric layer 14 includes a first main surface 14a and a second main surface 14b. The first main surface 14a and the second main surface 14b face each other. Of the first main surface 14a and the second main surface 14b, the second main surface 14b is a main surface on a side of a support member 13. In the present preferred embodiment, the piezoelectric layer 14 is a lithium niobate layer. More specifically, the piezoelectric layer 14 is a LiNbO₃ layer. However, the piezoelectric layer 14 may be a lithium tantalate layer, such as a LiTaO₃ layer.

Returning to FIG. 1, the first main surface 14a of the piezoelectric layer 14 is provided with the IDT electrode 11. The IDT electrode 11 includes a first busbar 16 and a second busbar 17, a plurality of first electrode fingers 18 and a plurality of second electrode fingers 19. The first electrode finger 18 is a first electrode. The plurality of first electrode fingers 18 is periodically disposed. Each of one ends of the plurality of first electrode fingers 18 is connected to the first busbar 16. The second electrode finger 19 is a second electrode in the present invention. The plurality of second electrode fingers 19 is periodically disposed. Each of one ends of the plurality of second electrode fingers 19 is connected to the second busbar 17. The plurality of first electrode fingers 18 and the plurality of second electrode fingers 19 are interdigitated with each other.

In the present preferred embodiment, the IDT electrode 11 includes Al. However, the material of the IDT electrode 11 is not limited to the above. The IDT electrode 11 may be formed of a single-layer metal film, or may be formed of a multilayer metal film. Note that, hereinafter, the first electrode finger 18 and the second electrode finger 19 may be simply referred to as the electrode fingers. The electrode finger is an electrode. Further, the first busbar 16 and the second busbar 17 may be simply referred to as the busbars.

In the acoustic wave device 10, an acoustic wave is excited by applying an AC voltage to the IDT electrode 11. In the acoustic wave device 10, a bulk wave in a thickness shear mode is utilized as a main wave. More specifically, in the acoustic wave device 10, a bulk wave in a thickness shear primary mode is utilized as the main wave. Here, a ratio d/p is equal to or less than about 0.5 in the present preferred embodiment, when a thickness of the piezoelectric layer 14 is d and a center-to-center distance between the electrode fingers adjacent to each other is p. As a result, the above thickness shear mode is suitably excited. Note that, the functional electrode is not limited to the IDT electrode 11. It is sufficient that the functional electrode includes at least one pair of electrodes.

As illustrated in FIG. 2, the first main surface 14a of the piezoelectric layer 14 is provided with a first dielectric film 15A. To be more specific, the first dielectric film 15A is provided on a portion located between the electrode fingers, on the first main surface 14a. Note that, the first dielectric film 15A may also be provided on, for example, a portion located between each busbar and each electrode finger, on the first main surface 14a. In the present preferred embodiment, silicon oxide is used for the first dielectric film 15A. However, the material of the first dielectric film 15A is not limited to the above, and for example, may include at least one material among silicon nitride, aluminum nitride, tantalum oxide, niobium oxide, and hafnium oxide. Note that, when the IDT electrode 11 includes Al, the first dielectric film 15A preferably includes at least one material among silicon oxide, silicon nitride, and aluminum nitride.

The first dielectric film 15A includes a first surface 15a and a second surface 15b. The first surface 15a and the second surface 15b face each other in a thickness direction. Of the first surface 15a and the second surface 15b, the second surface 15b is a surface on a side of the piezoelectric layer 14. A distance between the first surface 15a and the second surface 15b is a thickness of the first dielectric film 15A. Alternatively, the thickness of the first dielectric film 15A is a distance between the first main surface 14a of the piezoelectric layer 14, and the first surface 15a of the first dielectric film 15A. Further, each first electrode finger 18 includes a third surface 18a and a fourth surface 18b. The third surface 18a and the fourth surface 18b face each other in the thickness direction. Of the third surface 18a and the fourth surface 18b, the fourth surface 18b is a surface located on a side of the piezoelectric layer 14. A distance between the third surface 18a and the fourth surface 18b is a thickness of the first electrode finger 18. Similarly, each second electrode finger 19 also includes a third surface 19a and a fourth surface 19b.

In the present preferred embodiment, the thickness of each electrode finger and the thickness of the first dielectric film 15A are the same. The third surface of each electrode finger and the first surface 15a of the first dielectric film 15A are flush with each other. A second dielectric film 15B is provided across the first surface 15a of the first dielectric film 15A and the third surface of each electrode finger. Silicon nitride is used for the second dielectric film 15B. However, the material of the second dielectric film 15B is not limited to the above, and for example, it is also possible to use silicon oxide, aluminum nitride, tantalum oxide, niobium oxide, hafnium oxide, or the like.

Incidentally, in the present specification, the thickness direction and a height direction of the piezoelectric layer 14 and the like are parallel or substantially parallel to each other. That is, an up-down direction in FIG. 2, or the like is defined as the height direction. As positioning on an upper side in FIG. 2 or the like, it is defined as a higher position. For example, the second dielectric film 15B is located above the first dielectric film 15A.

The present preferred embodiment is characterized in that d/p is equal to or less than about 0.5, and the first surface 15a of the first dielectric film 15A is at a same height or higher than the third surface of each electrode finger. Note that, the first surface 15a may be disposed at a position higher than the third surface of each electrode finger. This makes it possible to reduce or prevent a response of an unnecessary wave. Further, in the present preferred embodiment, the second dielectric film 15B is provided across the first surface 15a and each third surface. This makes it possible to protect the IDT electrode 11, and accordingly, the IDT electrode 11 is less likely to be damaged. Details of effects of reducing or preventing an unnecessary wave will be described below, by comparing a first modification example of the present preferred embodiment with a comparative example.

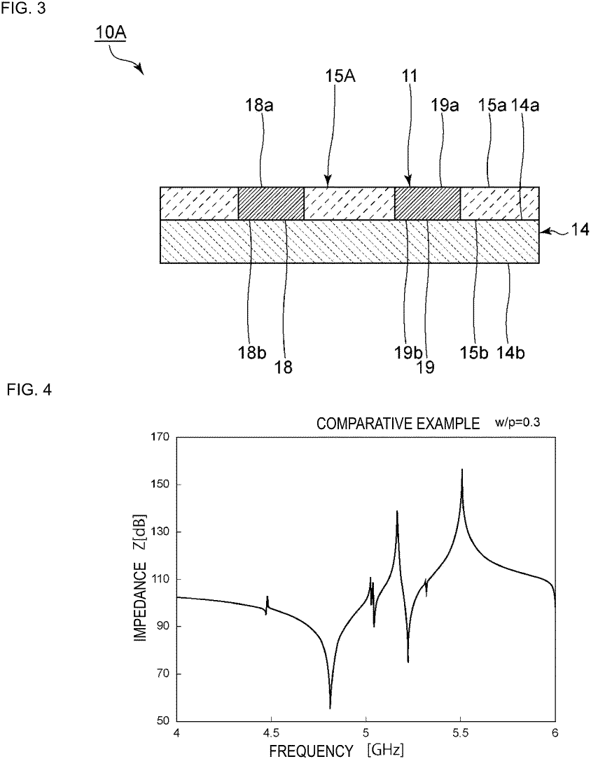

FIG. 3 is a front cross-sectional view, of an acoustic wave device according to the first modification example of the first preferred embodiment, illustrating a vicinity of one pair of electrode fingers.

The present modification example is different from the first preferred embodiment in that the second dielectric film 15B is not provided. Except for the above point, an acoustic wave device 10A of the present modification example has a configuration similar to that of the acoustic wave device 10 of the first preferred embodiment. On the other hand, the comparative example is different from the first preferred embodiment in that the first dielectric film 15A and the second dielectric film 15B are not provided. Impedance-frequency characteristics of the first modification example of the first preferred embodiment and the comparative example were compared.

Note that, the first electrode finger 18 and the second electrode finger 19 face each other on the first main surface 14a of the piezoelectric layer 14. A dimension of the electrode finger along a direction in which the electrode fingers face each other is defined as a width w of the electrode finger. Then, as described above, the center-to-center distance between the adjacent electrode fingers to each other is p. The impedance-frequency characteristics of the acoustic wave device 10A according to the first modification example of the first preferred embodiment were measured each time w/p, which is a ratio of the width w and the center-to-center distance p, was changed. Similarly, the impedance-frequency characteristics of the comparative example were measured each time w/p was changed. Specifically, in each of the first modification example and the comparative example, w/p was set to about 0.3, about 0.4, or about 0.5. Design parameters other than w/p in the acoustic wave device 10A of the first modification example are as follows.
Piezoelectric layer; material: ZY cut LiNbO₃, thickness: 400 nm
IDT electrode; material: A1, thickness: 100 nm
First dielectric film; material: SiO₂, thickness: 100 nm

On the other hand, design parameters other than w/p in the comparative example are as follows.
Piezoelectric layer; material: ZY cut LiNbO₃, thickness: 400 nm
IDT electrode; material: A1, thickness: 100 nm

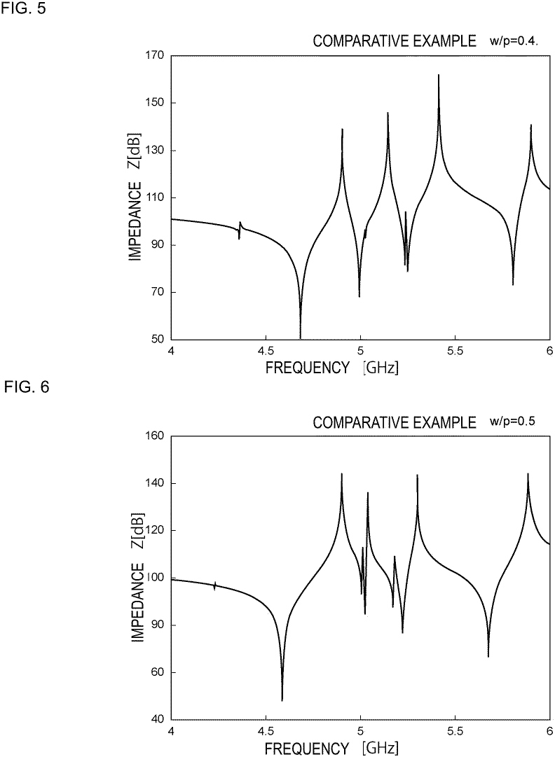

FIG. 4 is a graph, of the comparative example, showing the impedance-frequency characteristics when w/p is about 0.3. FIG. 5 is a graph, of the comparative example, showing the impedance-frequency characteristics when w/p is about 0.4. FIG. 6 is a graph, of the comparative example, showing the impedance-frequency characteristics when w/p is about 0.5.

As shown in FIG. 4, FIG. 5, and FIG. 6, in the comparative example, it can be seen that a large response of an unnecessary wave occurs, regardless of values of w/p.

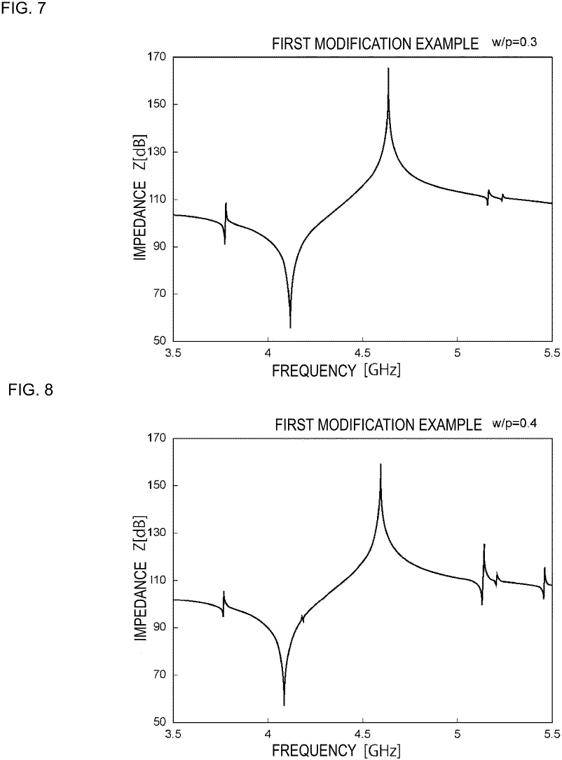

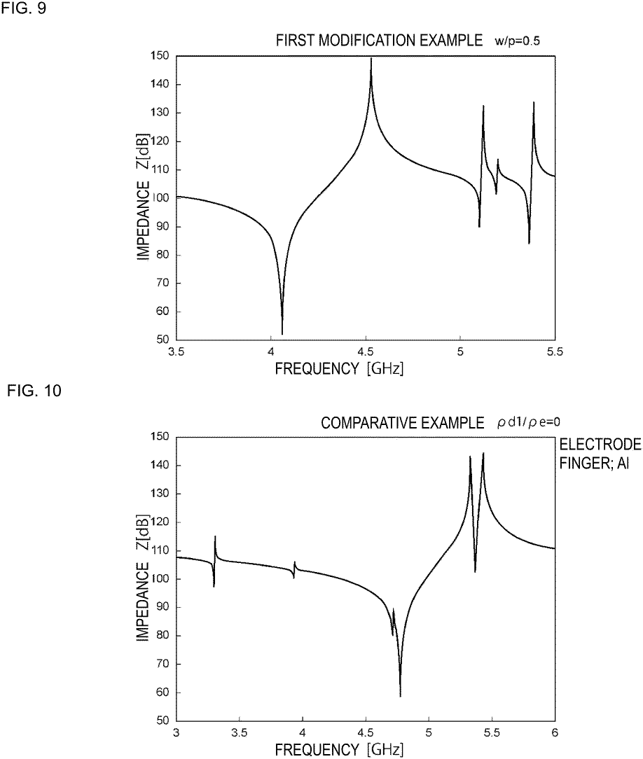

FIG. 7 is a graph, of the first modification example of the first preferred embodiment of the present invention, showing the impedance-frequency characteristics when w/p is about 0.3. FIG. 8 is a graph, of the first modification example of the first preferred embodiment, showing the impedance-frequency characteristics when w/p is about 0.4. FIG. 9 is a graph, of the first modification example of the first preferred embodiment, showing the impedance-frequency characteristics when w/p is about 0.5.

As shown in FIG. 7, FIG. 8, and FIG. 9, in various preferred embodiments of the present invention, the response of the unnecessary wave can be reduced or prevented, regardless of the values of w/p. In the first modification example of the first preferred embodiment of the present invention, the first surface 15a of the first dielectric film 15A is at the same height or higher than the third surface of each electrode finger. With this configuration, reflectivity of a spurious mode that propagates in a lateral direction can be reduced. Accordingly, it is possible to reduce or prevent the response of the unnecessary wave. Note that, the lateral direction is a direction in which the electrode finger extends.

Similarly, also in the first preferred embodiment, the first surface 15a of the first dielectric film 15A is at the same height or higher than the third surface of each electrode finger. Thus, it is possible to reduce or prevent the response of the unnecessary wave.

In the following, details of the configuration of the first preferred embodiment will be described.

As illustrated in FIG. 2, the piezoelectric substrate 12 includes the support member 13 and the piezoelectric layer 14. In the present preferred embodiment, the support member 13 is a support substrate. The support substrate is a silicon substrate in the present preferred embodiment. However, the material of the support substrate is not limited to the above.

The support member 13 is provided with a through-hole 13a, as a cavity portion or an air gap. The piezoelectric layer 14 covers the through-hole 13a of the support member 13. Thus, the second main surface 14b of the piezoelectric layer 14 faces the air gap.

The cavity portion is not limited to the through-hole. The cavity portion may be, for example, a hollow portion. The hollow portion is, for example, a recessed portion provided in the support member. More specifically, the hollow portion is formed by sealing the recessed portion with the piezoelectric layer 14 or the like. Alternatively, the piezoelectric layer 14 may be provided with a recessed portion that opens toward the support member 13 side. Thus, the cavity portion may be formed. In this case, the support member 13 need not be provided with a recessed portion or a through-hole. Alternatively, an acoustic multilayer film may be provided between the support member 13 and the piezoelectric layer 14. In this case, the support member 13 and the piezoelectric layer 14 need not be provided with a cavity portion.

Note that, the support member 13 may be, for example, a laminated body including a support substrate and an insulating layer. In this case, the piezoelectric layer 14 is provided on the insulating layer. As a material of the insulating layer, for example, a silicon oxide layer, silicon nitride, tantalum oxide, or the like can be used.

Hereinafter, preferred configurations of the present invention will be described.

Impedance-frequency characteristics are shown when an elastic modulus and a density of the first dielectric film 15A are changed, in the configuration of the first modification example by simulation. More particularly, when the density of the first dielectric film 15A is pd1, a density of the electrode finger is pe, and a density ratio of the first dielectric film 15A and the electrode finger is pd1/pe, pd1/pe was set to about 0.4, about 0.6 or about 0.8. In this simulation, the electrode finger was made of A1. Thus, the density pe is a density of A1. Then, the density pd1 was changed, and pd1/pe was set to the above value. On the other hand, the elastic modulus of the first dielectric film 15A is also an elastic modulus of A1. Note that, simulation results of the comparative example are additionally shown. The simulation of the comparative example was performed under conditions similar to those for the acoustic wave device having the configuration of the first modification example, except that the first dielectric film 15A is not included.

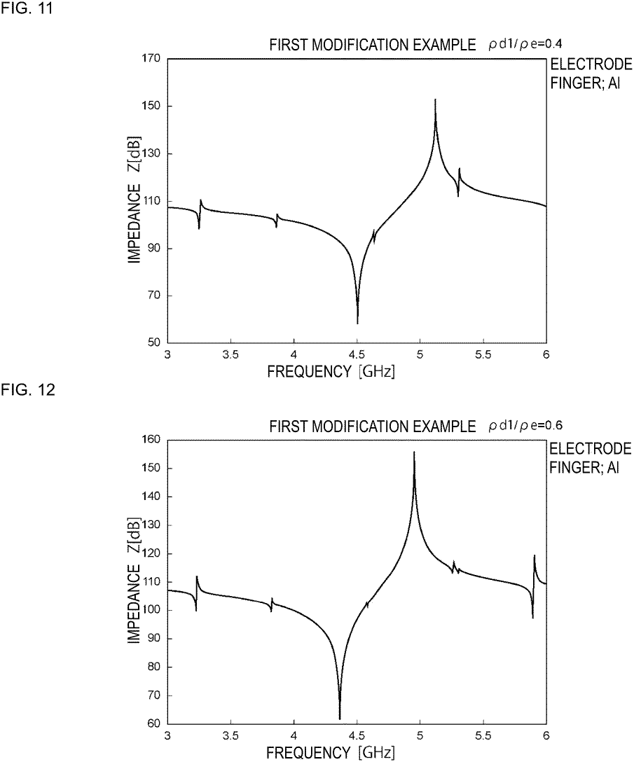

FIG. 10 is a graph, of the comparative example, showing impedance-frequency characteristics when the electrode finger is made of A1. FIG. 11 is a graph, of the first modification example of the first preferred embodiment of the present invention, showing impedance-frequency characteristics when the electrode finger is made of A1, and pd1/pe is about 0.4. FIG. 12 is a graph, of the first modification example of the first preferred embodiment, showing impedance-frequency characteristics when the electrode finger is made of A1, and pd1/pe is about 0.6. FIG. 13 is a graph, of the first modification example of the first preferred embodiment, showing impedance-frequency characteristics when the electrode finger is made of A1, and pd1/pe is about 0.8.

As shown in FIG. 10, in the comparative example, in the impedance-frequency characteristics, large ripples occur in a band between a resonant frequency and an anti-resonant frequency, and in a band in a vicinity thereof. This ripple is due to a response of an unnecessary wave. On the other hand, as shown in FIG. 11, it can be seen that in various preferred embodiments of the present invention, the ripple is reduced or prevented in each of the above bands. Further, as shown in FIG. 12 and FIG. 13, when pd1/pe is about 0.6, and when pd1/pe is about 0.8, the ripple is further reduced or prevented in each of the above bands. As described above, the density pd1 of the first dielectric film 15A is preferably about 0.6 times or greater than the density pe of the electrode finger, more preferably about 0.8 times or greater. Thus, it is possible to further reduce or prevent the response of the unnecessary wave in the band between the resonant frequency and the anti-resonant frequency, and in the band in the vicinity thereof.

Further, simulation was performed while changing the conditions. In this simulation, the electrode finger was made of Cu. Thus, the density pe is a density of Cu. Then, the density pd1 was changed, and pd1/pe was set to about 0.4, about 0.6, or about 0.8. On the other hand, the elastic modulus of the first dielectric film 15A is also an elastic modulus of Cu. Note that, simulation results of the comparative example are additionally shown. The simulation of the comparative example was performed under conditions similar to those for the acoustic wave device having the configuration of the first modification example, except that the first dielectric film 15A is not included.

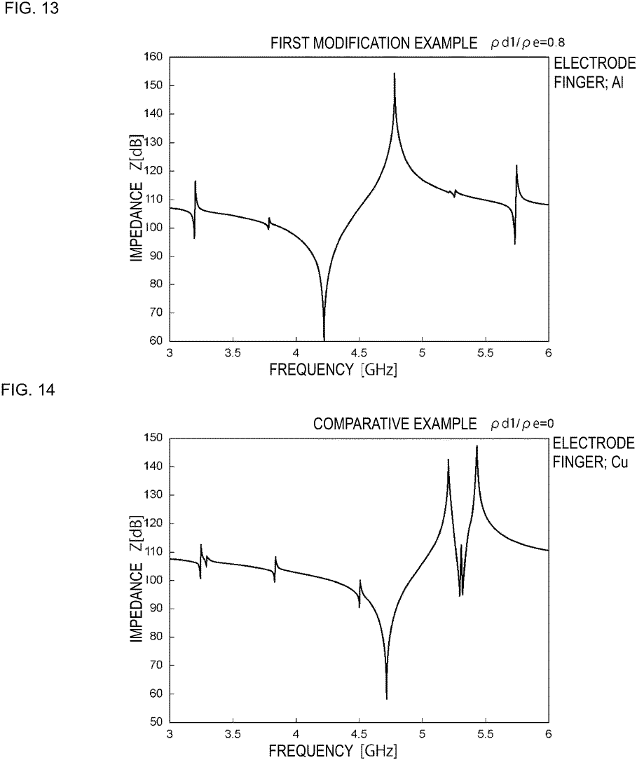

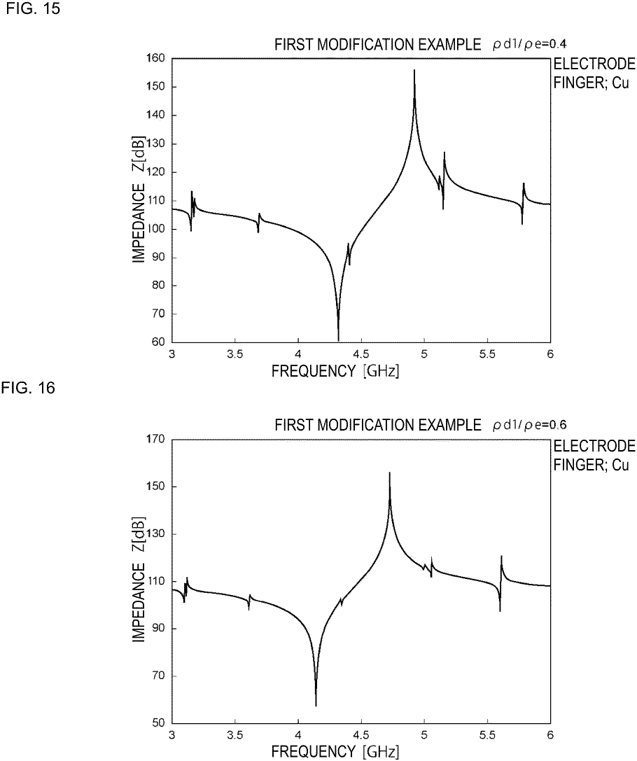

FIG. 14 is a graph, of the comparative example, showing impedance-frequency characteristics when the electrode finger is made of Cu. FIG. 15 is a graph, of the first modification example of the first preferred embodiment of the present invention, showing impedance-frequency characteristics when the electrode finger is made of Cu, and pd1/pe is about 0.4. FIG. 16 is a graph, of the first modification example of the first preferred embodiment, showing impedance-frequency characteristics when the electrode finger is made of Cu, and pd1/pe is about 0.6. FIG. 17 is a graph, of the first modification example of the first preferred embodiment, showing impedance-frequency characteristics when the electrode finger is made of Cu, and pd1/pe is about 0.8.

As shown in FIG. 14, in the comparative example, a large ripple occurs in the impedance-frequency characteristics. On the other hand, as shown in FIG. 15, it can be seen that in various preferred embodiments of the present invention, the ripple is reduced or prevented. Further, as shown in FIG. 16 and FIG. 17, when pd1/pe is about 0.6, and when pd1/pe is about 0.8, the ripple is further suppressed. As described above, even when the electrode finger is made of Cu, the density pd1 of the first dielectric film 15A is preferably about 0.6 times or greater than the density pe of the electrode finger, and more preferably about 0.8 times or greater, as in the case where the electrode finger is made of A1. This makes it possible to further reduce or prevent the response of the unnecessary wave.

Incidentally, in the first preferred embodiment, d/p is equal to or less than about 0.5, when the thickness of the piezoelectric layer 14 is d and the center-to-center distance of the adjacent electrode fingers is p. Thus, p/d is equal to or greater than about 2. The same applies to the first modification example. In the following, impedance-frequency characteristics will be shown, when p/d is changed, in the configuration of the first modification example, by simulation. More specifically, p/d was set to about 4, about 5, about 6, or about 7. Note that, the number of electrode fingers was 60.

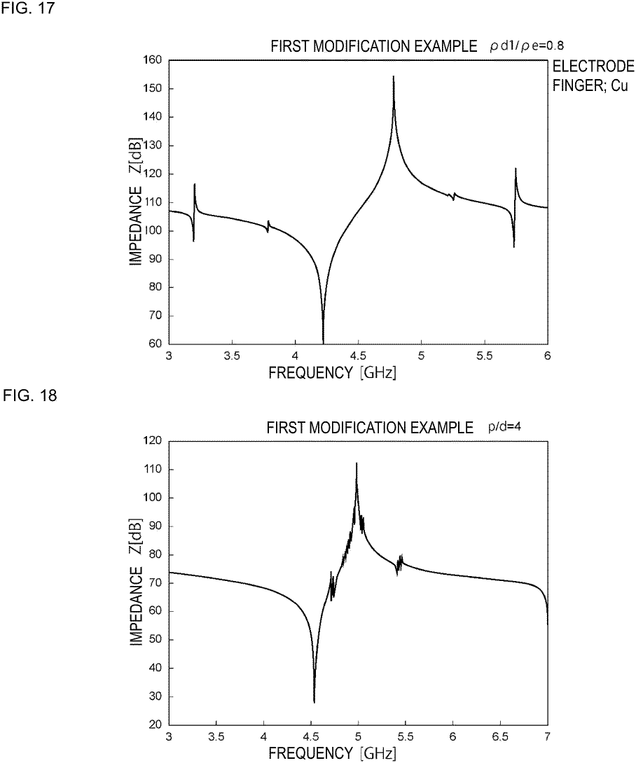

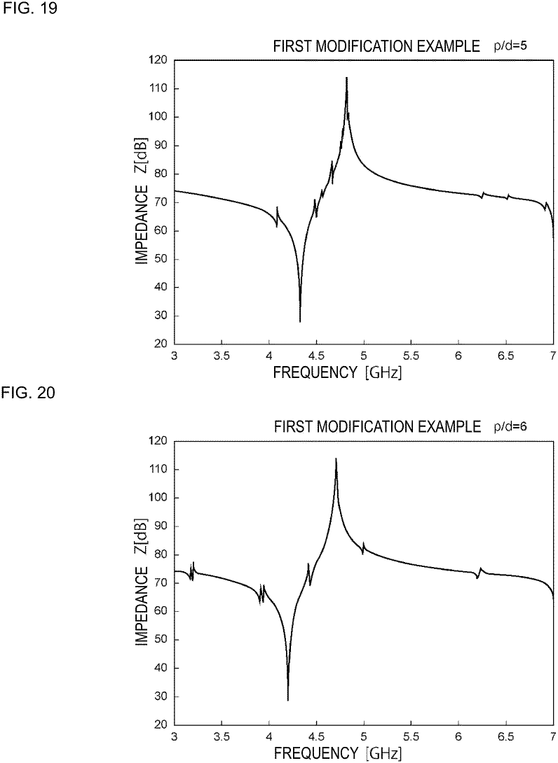

FIG. 18 is a graph, of the first modification example of the first preferred embodiment, showing impedance-frequency characteristics when p/d is about 4. FIG. 19 is a graph, of the first modification example of the first preferred embodiment, showing impedance-frequency characteristics when p/d is about 5. FIG. 20 is a graph, of the first modification example of the first preferred embodiment, showing impedance-frequency characteristics when p/d is about 6. FIG. 21 is a graph, of the first modification example of the first preferred embodiment, showing impedance-frequency characteristics when p/d is about 7.

As illustrated in FIG. 18 and FIG. 19, when p/d is about 4, and when p/d is about 5, the ripple due to the response of the unnecessary wave is relatively reduced or prevented. Further, as shown in FIG. 20 and FIG. 21, when p/d is about 6, and when p/d is about 7, the ripple is further reduced or prevented. Thus, p/d is preferably equal to or greater than about 6, and more preferably equal to or greater than about 7. This makes it possible to further reduce or prevent the response of the unnecessary wave.

In the above, the preferable example in the configuration of the first modification example of the first preferred embodiment has been described. However, each of the above-described configurations serves as a preferable configuration, similarly even when the second dielectric film 15B is provided as in the first preferred embodiment.

In the first preferred embodiment, the respective materials of the first dielectric film 15A and the second dielectric film 15B are different from each other. However, the first dielectric film 15A and the second dielectric film 15B may be made of the same material. For example, silicon oxide may be used for both the first dielectric film 15A and the second dielectric film 15B.

In the first preferred embodiment, a thickness of the second dielectric film 15B is less than the thickness of the first dielectric film 15A. To be more specific, for example, when the thickness of the piezoelectric layer 14 is about 400 nm, and the thickness of the first dielectric film 15A is about 100 nm, the thickness of the second dielectric film 15B is about 20 nm. However, the relationship of the thickness of each layer is not limited to the above.

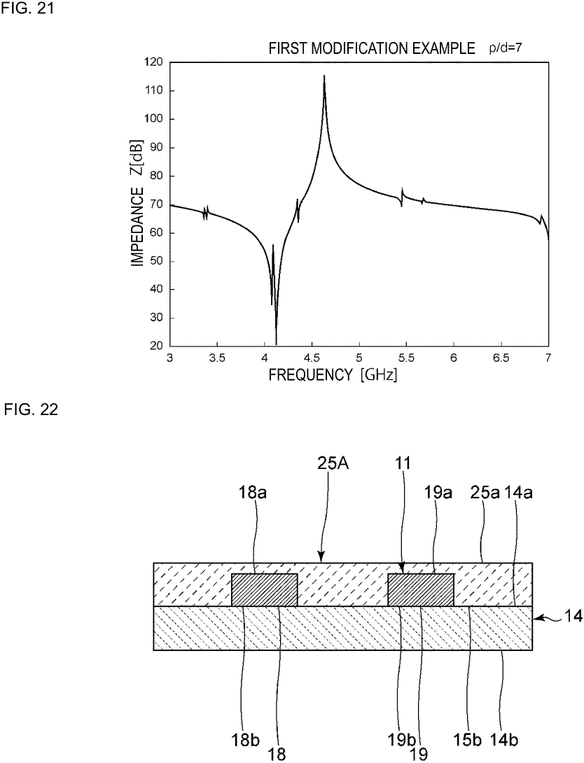

As illustrated in FIG. 3, in the first modification example, the first surface 15a of the first dielectric film 15A is at the same height as the third surface 18a of the first electrode finger 18 and the third surface 19a of the second electrode finger 19. However, the present invention is not limited thereto. In a second modification example of the first preferred embodiment illustrated in FIG. 22, a first surface 25a of a first dielectric film 25A is higher than the third surface of each electrode finger. Further, the first dielectric film 25A covers the third surface of each electrode finger. Even in this case, it is possible to reduce or prevent the response of the unnecessary wave. Note that, the second dielectric film 15B illustrated in FIG. 2 may be provided on the first surface 25a of the first dielectric film 25A in the second modification example.

FIG. 23 is a front cross-sectional view, of an acoustic wave device according to a second preferred embodiment, illustrating a vicinity of one pair of the electrode fingers.

The present preferred embodiment is different from the first preferred embodiment in that the first dielectric film 15A and a second dielectric film 35B are made of the same material, and in that the second dielectric film 35B includes a plurality of projecting portions 35c. Except for the above points, the acoustic wave device of the present preferred embodiment has a configuration similar to that of the acoustic wave device 10 of the first preferred embodiment.

Note that, as in the present preferred embodiment, when the first dielectric film 15A and the second dielectric film 35B are made of the same material, the thickness of the first dielectric film 15A is the same as the thickness of each electrode finger. Thus, the thickness of the first dielectric film 15A is a thickness from the first main surface 14a of the piezoelectric layer 14 to the third surface of each electrode finger. In this case, the second dielectric film 35B is provided across the first surface 15a of the first dielectric film 15A and the third surface of each electrode finger, as in the first preferred embodiment. Although a boundary between the first dielectric film 15A and the second dielectric film 35B is described in FIG. 23, the boundary between the first dielectric film 15A and the second dielectric film 35B is not actually provided when the first dielectric film 15A and the second dielectric film 35B are made of the same material.

The second dielectric film 35B includes a first surface 35a and a second surface 35b. The first surface 35a and the second surface 35b face each other in the thickness direction. Of the first surface 35a and the second surface 35b, the second surface 35b is located on a side of the first dielectric film 15A. A surface of the second dielectric film 35B on a side opposite to the side of the first dielectric film 15A is the first surface 35a. The first surface 35a is provided with the plurality of projecting portions 35c. In plan view, each projecting portion 35c overlaps the first electrode finger 18 or the second electrode finger 19. In the present specification, “in plan view” refers to a direction viewing from above in FIG. 1, FIG. 23, or the like.

The projecting portion 35c has an upper surface 35d. Note that, the upper surface 35d is a surface located on an upper side in an up-down direction in FIG. 23. A thickness of the projecting portion 35c is a distance between the first surface 35a of the second dielectric film 35B, and the upper surface 35d of the projecting portion 35c.

In the following, impedance-frequency characteristics in the present preferred embodiment will be described. Note that, impedance-frequency characteristics when h/td1 = 1.2 will be described, when a thickness of the projecting portion 35c is h, a thickness of the first dielectric film 15A is td1, and a thickness ratio is h/tdl. Impedance-frequency characteristics of the first preferred embodiment when h/td1 = 0 will be additionally shown.

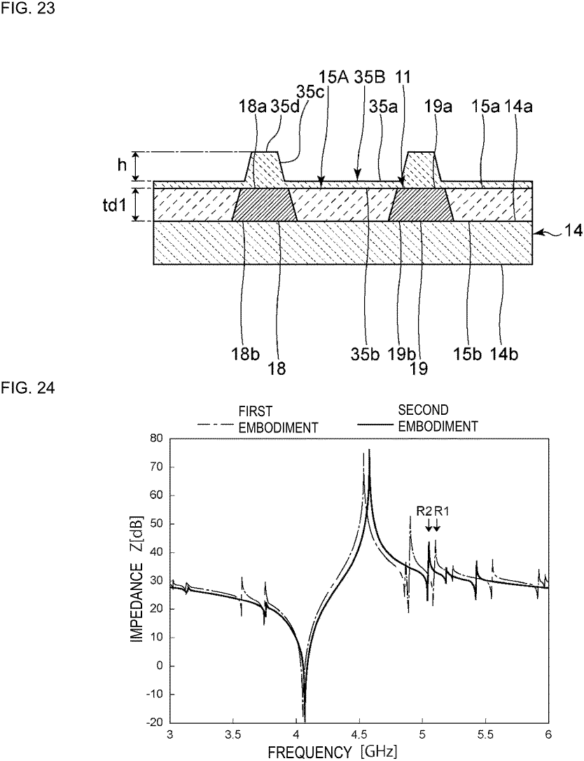

FIG. 24 is a graph showing the impedance-frequency characteristics in the first preferred embodiment and the second preferred embodiment. An arrow R1 in FIG. 24 indicates one of ripples in the first preferred embodiment. An arrow R2 indicates a ripple in the second preferred embodiment corresponding to the ripple indicated by the arrow R1.

As shown in FIG. 24, in both the first preferred embodiment and the second preferred embodiment, the unnecessary waves are reduced or prevented in the band between the resonant frequency and the anti-resonant frequency, and in the band in the vicinity thereof. Note that, as indicated by the arrow R1 and the arrow R2 in FIG. 24, in a higher frequency side than the anti-resonant frequency, the ripple is located on a further higher frequency side, in the first preferred embodiment, as compared with the second preferred embodiment. Thus, in the first preferred embodiment, the response of the unnecessary wave in the vicinity of the anti-resonant frequency is further reduced. Thus, the anti-resonant frequency in the first preferred embodiment is located on the higher frequency side, as compared with the second preferred embodiment. Thus, a value of a fractional bandwidth is increased. Note that, the fractional bandwidth referred to here is represented by a formula (|fa - fr|/fr) × 100[%], when the resonant frequency is fr, and the anti-resonant frequency is fa.

Further, the resonant frequency and the anti-resonant frequency were measured each time the thickness ratio h/td1 was changed, and the fractional bandwidth was calculated. By using this, a relationship between the thickness ratio (h/td1) × 100[%] and the fractional bandwidth was obtained.

FIG. 25 is a graph showing the relationship between thickness ratio (h/td1) × 100[%] and the fractional bandwidth.

As shown in FIG. 25, it can be seen that as the thicknesses ratio (h/td1) × 100 decreases, a value of the fractional bandwidth increases. The thickness ratio is preferably equal to or less than about 60%. Note that, as described above, the thickness td1 of the first dielectric film 15A is the thickness of the first dielectric films 15A from the first main surface 14a of the piezoelectric layer 14 to the third surface of each electrode finger. Thus, the thickness h of the projecting portion 35c of the second dielectric film 35B is preferably about 0.6 times or less than the above thickness td1 of the first dielectric film 15A. In this case, the value of the fractional bandwidth can be effectively increased. The thickness ratio is more preferably equal to or less than about 15%. That is, the thickness h of the projecting portion 35c is more preferably about 0.15 times or less than the above thickness td1 of the first dielectric film 15A. As a result, it is possible to further increase the value of the fractional bandwidth.

Hereinafter, a third preferred embodiment and a fourth preferred embodiment of the present invention will be described. Also in these cases, it is possible to reduce or prevent the response of the unnecessary wave, as in the first preferred embodiment.

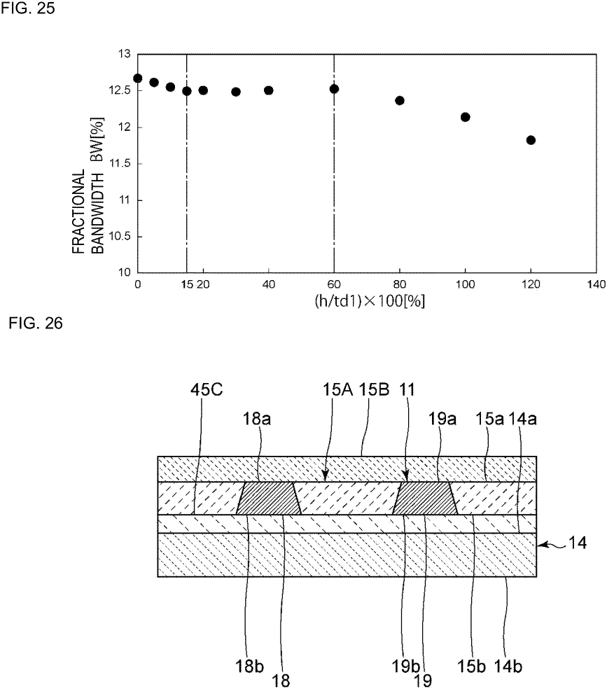

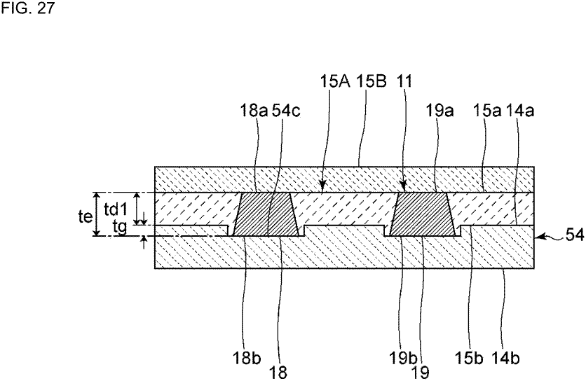

FIG. 26 is a front cross-sectional view, of an acoustic wave device according to the third preferred embodiment, illustrating a vicinity of one pair of the electrode fingers.

The present preferred embodiment is different from the first preferred embodiment in that a third dielectric film 45C is provided between the piezoelectric layer 14 and the IDT electrode 11, and in a cross-sectional shape of the electrode finger. Except for the above points, the acoustic wave device of the present preferred embodiment has a configuration similar to that of the acoustic wave device 10 of the first preferred embodiment. In the present preferred embodiment, a fractional bandwidth can be suitably adjusted in accordance with a thickness of the third dielectric film 45C. As illustrated in FIG. 26, a side surface of the electrode finger may be inclined with respect to a thickness direction of the electrode finger. The side surface of the electrode finger is a surface connected to the first surface and the second surface of the electrode finger. However, the side surface of the electrode finger may extend in parallel or substantially in parallel with the thickness direction of the electrode finger, as in the first preferred embodiment.

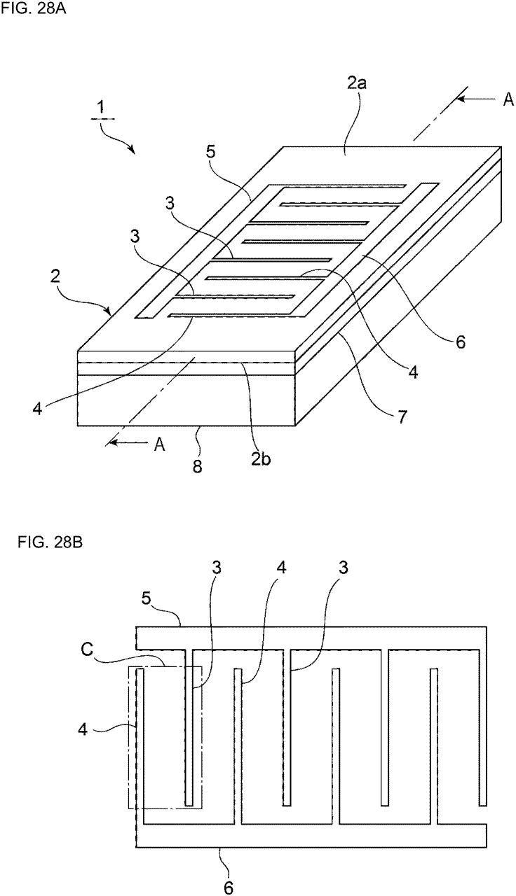

FIG. 27 is a front cross-sectional view, of an acoustic wave device according to the fourth preferred embodiment, illustrating a vicinity of one pair of the electrode fingers.

The present preferred embodiment is different from the first preferred embodiment in that a plurality of recessed portions 54c is provided in the first main surface 14a of a piezoelectric layer 54, and in that each electrode finger is provided in each recessed portion 54c. The first dielectric film 15A reaches inside the plurality of recessed portions 54c. Furthermore, the present preferred embodiment is different from the first preferred embodiment also in that a side surface of the electrode finger is inclined with respect to the thickness direction of the electrode finger. Except for the above points, the acoustic wave device of the present preferred embodiment has a configuration similar to that of the acoustic wave device 10 of the first preferred embodiment.

As described above, the thickness of the first dielectric film 15A is td1. Note that, the thickness td1 in the present preferred embodiment is the distance between the first main surface 14a of the piezoelectric layer 14, and the first surface 15a of the first dielectric film 15A, as in the case where the recessed portion 54c is not provided. It is sufficient that te ≤ td1 + tg holds, when the thickness of the electrode finger is te, and a depth of the recessed portion 54c is tg. In this case, the first surface 15a of the first dielectric film 15A is at the same height or higher than the third surface 18a of the first electrode finger 18 and the third surface 19a of the second electrode finger 19.

In the present preferred embodiment, each electrode finger is provided inside the recessed portion 54c, thus a height of the third surface of each electrode finger is lower than that in the case of the first preferred embodiment. Thus, as compared with the first preferred embodiment, the first surface 15a of the first dielectric film 15A is at the same height or higher than the third surface of each electrode finger, even when the thickness of each electrode finger is increased. As described above, the thickness of each electrode finger can be increased, thus electric resistance of the IDT electrode 11 can be reduced. Thus, when the acoustic wave device of the present preferred embodiment is used in a filter device, filter characteristics can be improved.

Hereinafter, a thickness shear mode will be described in detail. Note that, in the following, description will be given using an example in which the first dielectric film and the second dielectric film are not provided. However, even when the first dielectric film and the second dielectric film are provided, as in each of the above-described preferred embodiments, description similar to the following holds. Here, a support member in the following example corresponds to the support substrate.

FIG. 28A is a schematic perspective view illustrating an external appearance of an acoustic wave device in which a bulk wave in the thickness shear mode is utilized, FIG. 28B is a plan view illustrating electrode structure on a piezoelectric layer, and FIG. 29 is a cross-sectional view of a portion taken along the line A-A in FIG. 28A.

The acoustic wave device 1 includes a piezoelectric layer 2 made of LiNbO₃. The piezoelectric layer 2 may be made of LiTaO₃. A cut-angle of LiNbO₃ or LiTaO₃ is Z-cut, but may also be rotational Y-cut or X-cut. A thickness of the piezoelectric layer 2 is not particularly limited, but in order to effectively excite the thickness shear mode, is preferably equal to or greater than about 40 nm and equal to or less than about 1000 nm, and more preferably equal to or greater than about 50 nm and equal to or less than about 1000 nm. The piezoelectric layer 2 includes first and second main surfaces 2a and 2b facing each other. An electrode 3 and an electrode 4 are provided on the first main surface 2a. Here, the electrode 3 is an example of the “first electrode”, and the electrode 4 is an example of the “second electrode”. In FIGS. 28A and 28B, a plurality of the electrodes 3 is connected to a first busbar 5. A plurality of the electrodes 4 is connected to a second busbar 6. The electrodes 3 and the electrodes 4 are interdigitated with each other. The electrode 3 and the electrode 4 each have a rectangular or substantially rectangular shape, and have a length direction. The electrode 3 and the electrode 4 adjacent thereto face each other in a direction orthogonal to the length direction. The length direction of the electrodes 3 and 4, and the direction orthogonal to the length direction of the electrodes 3 and 4, are both directions intersecting the thickness direction of the piezoelectric layer 2. Thus, it can also be said that the electrode 3 and the adjacent electrode 4 face each other in the direction intersecting the thickness direction of the piezoelectric layer 2. Further, the length direction of the electrodes 3 and 4 may be replaced with a direction orthogonal to the length direction of the electrodes 3 and 4 illustrated in FIGS. 28A and 28B. That is, in FIGS. 28A and 28B, the electrodes 3 and 4 may be extended in a direction in which the first busbar 5 and the second busbar 6 extend. In this case, the first busbar 5 and the second busbar 6 extend in the direction in which the electrodes 3 and 4 extend in FIGS. 28A and 28B. Then, one pair of structures in which the electrode 3 connected to one potential and the electrode 4 connected to another potential are adjacent to each other, are plurally provided in the direction orthogonal to the length direction of the electrodes 3 and 4. Here, the electrode 3 and the electrode 4 being adjacent to each other refers to a case where the electrode 3 and the electrode 4 are disposed with a gap interposed therebetween, rather than to a case where the electrode 3 and the electrode 4 are disposed so as to be in direct contact with each other. In addition, when the electrode 3 and the electrode 4 are adjacent to each other, electrodes connected to a hot electrode or a ground electrode, including the other electrodes 3 and 4, are not disposed between the electrode 3 and the electrode 4. The number of pairs need not be an integer, but may be 1.5, 2.5, or the like. A center-to-center distance between the electrodes 3 and 4, that is, a pitch is preferably in a range from about 1 µm to about 10 µm inclusive. In addition, a width of the electrode 3 or 4, that is, a dimension in a direction in which the electrode 3 and 4 face each other is preferably in a range from about 50 nm to about 1000 nm inclusive, more preferably in a range from about 150 nm to about 1000 nm inclusive. Note that, the center-to-center distance between the electrodes 3 and 4 is a distance that links a center of the dimension (width dimension) of the electrode 3 in the direction orthogonal to the length direction of the electrode 3, with a center of the dimension (width dimension) of the electrode 4 in the direction orthogonal to the length direction of the electrode 4.

Further, in the acoustic wave device 1, the Z-cut piezoelectric layer is used, thus the direction orthogonal to the length direction of the electrodes 3 and 4 is a direction orthogonal to a polarization direction of the piezoelectric layer 2. This is not the case, when a piezoelectric body having another cut-angle is used as the piezoelectric layer 2. Here, “orthogonal” is not limited only to a case of strictly orthogonal, but may be substantially orthogonal (an angle defined by the direction orthogonal to the length direction of the electrodes 3 and 4, and the polarization direction is in a range of about 90° ± 10°, for example).

A support member 8 is laminated on the piezoelectric layer 2 on a side of the second main surface 2b with an insulating layer 7 interposed therebetween. The insulating layer 7 and the support member 8 each have a frame shape, and have through-holes 7a and 8a, respectively, as illustrated in FIG. 29. A cavity portion or an air gap 9 is thus provided. The air gap 9 is provided at a position overlapping the electrodes 3 and 4 in plan view. In the present specification, “in plan view” refers to a direction viewing from above in FIG. 2. Note that, the support member 8 may be provided with a recessed portion instead of the through-hole 8a. The piezoelectric layer 2 faces the air gap 9. The air gap 9 is provided so as not to disturb a vibration of an excitation region C of the piezoelectric layer 2. Thus, the support member 8 is laminated on the second main surface 2b with the insulating layer 7 interposed therebetween, at a position not overlapping a portion where at least one pair of the electrodes 3 and 4 are provided. Note that, the insulating layer 7 need not be provided. Thus, the support member 8 may be directly or indirectly laminated on the second main surface 2b of the piezoelectric layer 2.

The insulating layer 7 preferably is made of silicon oxide, for example. However, in addition to silicon oxide, an appropriate insulating material such as silicon oxynitride, alumina or the like can be used. The support member 8 preferably is made of Si, for example. A plane orientation on a surface on a side of the piezoelectric layer 2 of Si may be (100), (110), or (111). Si of the support member 8 desirably has high resistance such that resistivity is equal to or greater than about 4 kQ. Of course, an appropriate insulating material or semiconductor material can also be used for the support member 8.

Examples of the material of the support member 8 include, for example, piezoelectric bodies such as aluminum oxide, lithium tantalate, lithium niobate, crystal and the like, various ceramics such as alumina, magnesia, sapphire, silicon nitride, aluminum nitride, silicon carbide, zirconia, cordierite, mullite, steatite, forsterite and the like, dielectrics such as diamond, glass and the like, and semiconductors such as gallium nitride.

The plurality of electrodes 3 and 4, and the first and second busbars 5 and 6 described above are made of appropriate metal or alloy, such as Al, an AlCu alloy or the like. In the present preferred embodiment, the electrodes 3 and 4 and the first and second busbars 5 and 6 each have structure in which an Al film is laminated on a Ti film. Note that, an adhesion layer other than the Ti film may be used.

At the time of driving, an AC voltage is applied between the plurality of electrodes 3 and the plurality of electrodes 4. More specifically, an AC voltage is applied between the first busbar 5 and the second busbar 6. This makes it possible to obtain resonance characteristics obtained by utilizing a bulk wave in the thickness shear mode excited in the piezoelectric layer 2. In addition, in the acoustic wave device 1, d/p is set to be equal to or less than about 0.5, when the thickness of the piezoelectric layer 2 is d and a center-to-center distance between any of the adjacent electrodes 3 and 4 to each other among the plurality of pairs of electrodes 3 and 4 is p. Thus, the bulk wave in the thickness shear mode described above is effectively excited, and good resonance characteristics can be obtained. More preferably, d/p is equal to or less than about 0.24, in this case, even better resonance characteristics can be obtained.

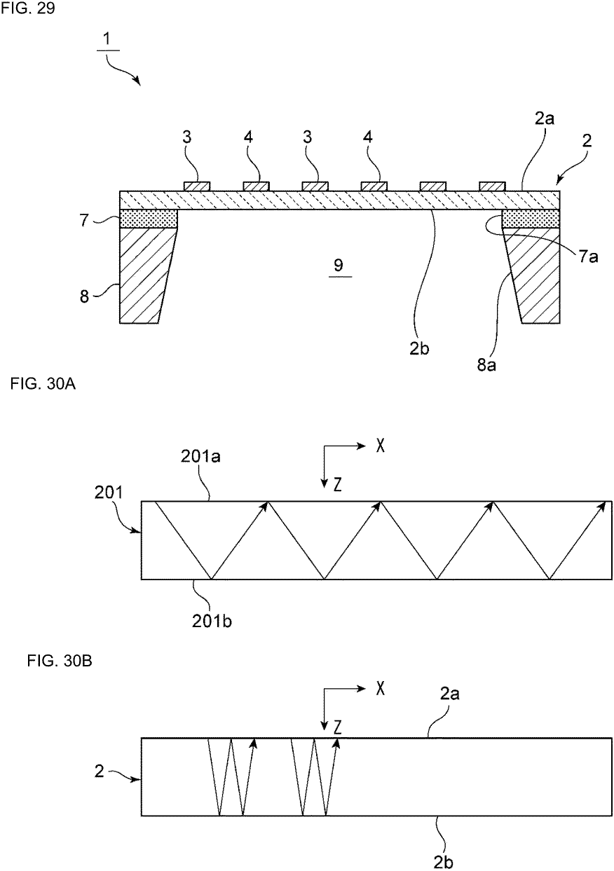

Since the acoustic wave device 1 is provided with the above-described configuration, even when the number of pairs of the electrodes 3 and 4 is reduced in order to attempt to achieve a reduction in size, a decrease in a Q value is less likely to occur. This is because a propagation loss is small, even when the number of electrode fingers in reflectors on both sides is reduced. Further, the reason why the number of the above electrode fingers can be reduced is that the bulk wave in the thickness shear mode is utilized. Differences between a Lamb wave used in an acoustic wave device, and the bulk wave in the thickness shear mode described above will be described, with reference to FIGS. 30A and 30B.

FIG. 30A is a schematic front cross-sectional view for explaining a Lamb wave propagating through a piezoelectric film of an acoustic wave device as described in U.S. Pat. No. 10,491,192. Here, a wave propagates inside a piezoelectric film 201 as indicated by arrows. Here, in the piezoelectric film 201, a first main surface 201a and a second main surface 201b face each other, and a thickness direction in which the first main surface 201a and the second main surface 201b are linked is a Z direction. An X direction is a direction in which electrode fingers of an IDT electrode are arranged. As illustrated in FIG. 30A, in the Lamb wave, the wave propagates in the X direction as illustrated. Because of a plate wave, the piezoelectric film 201 vibrates as a whole, but the wave propagates in the X direction, thus reflectors are disposed on both the sides to obtain resonance characteristics. Thus, a propagation loss of the wave occurs, and a Q value decreases when a reduction in size is attempted, that is, when the number of pairs of electrode fingers is reduced.

On the other hand, as illustrated in FIG. 30B, in the acoustic wave device 1, since vibration displacement is in a thickness shear direction, a wave propagates substantially in a direction in which the first main surface 2a and the second main surface 2b of the piezoelectric layer 2 are linked, that is, in the Z direction, and resonates. That is, an X direction component of the wave is significantly smaller than a Z direction component. Then, resonance characteristics are obtained by the propagation of the wave in the Z direction, a propagation loss is less likely to occur even when the number of electrode fingers of a reflector is reduced. Furthermore, even when the number of pairs of electrodes constituting the electrodes 3 and 4 is reduced in an attempt to promote a reduction in size, a Q value is less likely to decrease.

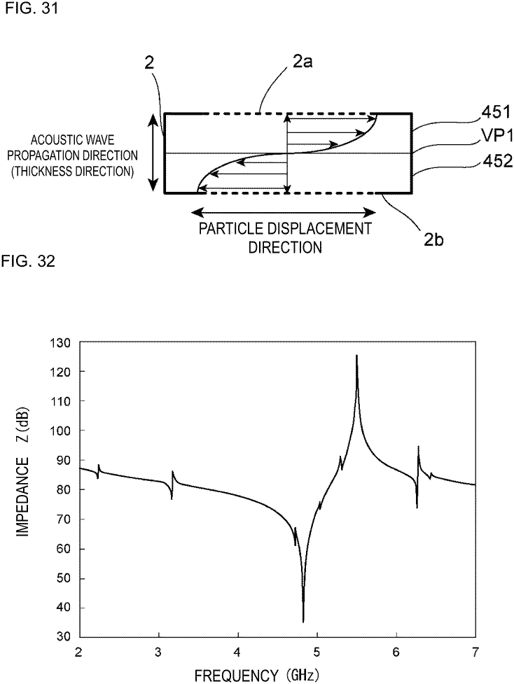

Note that, as illustrated in FIG. 31, an amplitude direction of the bulk wave in the thickness shear mode has an inverse relation between a first region 451 included in the excitation region C of the piezoelectric layer 2 and a second region 452 included in the excitation region C. In FIG. 31, a bulk wave, is schematically illustrated, when a voltage is applied between the electrode 3 and the electrode 4 such that the electrode 4 has a higher potential than that of the electrode 3. The first region 451 is a region, of the excitation region C, between a virtual plane VP1 that is orthogonal to the thickness direction of the piezoelectric layer 2 and divides the piezoelectric layer 2 into two parts, and the first main surface 2a. The second region 452 is a region, of the excitation region C, between the virtual plane VP1 and the second main surface 2b.

As described above, in the acoustic wave device 1, at least one pair of the electrodes 3 and 4 are provided, but waves are not propagated in the X direction, thus the number of pairs of electrodes 3 and 4 need not be plural. That is, it is sufficient that at least one pair of electrodes are provided.

For example, the electrode 3 is an electrode connected to a hot potential, and the electrode 4 is an electrode connected to a ground potential. However, the electrode 3 may be connected to the ground potential, and the electrode 4 may be connected to the hot potential. In the present preferred embodiment, as described above, at least one pair of the electrodes are an electrode connected to the hot potential or an electrode connected to the ground potential, and a floating electrode is not provided.

FIG. 32 is a graph showing resonance characteristics of the acoustic wave device illustrated in FIG. 29. Note that, design parameters of the acoustic wave device 1 that obtained these resonance characteristics are as follows.

Piezoelectric layer 2: LiNbO₃ having Euler angles (0°, 0°, 90°), a thickness = 400 nm.

When viewed in the direction orthogonal to the length direction of the electrodes 3 and 4, a region where the electrodes 3 and 4 overlap is as follows, that is, a length of the excitation region C = about 40 µm, the number of pairs of electrodes constituting the electrodes 3 and 4 = 21 pairs, a center-to-center distance between the electrodes = about 3 µm, a width of the electrode 3 or 4 = about 500 nm, d/p = about 0.133.

Insulating layer 7: silicon oxide film of a thickness of 1 µm.

Support member 8: Si.

Note that, the length of the excitation region C is a dimension of the excitation region C along the length direction of the electrodes 3 and 4.

In the present preferred embodiment, electrode-to-electrode distances of the plurality of pairs of electrodes constituting the electrodes 3 and 4 were all made the same. That is, the electrodes 3 and the electrodes 4 were disposed at equal pitches.

As is clear from FIG. 32, good resonance characteristics with a fractional bandwidth of about 12.5% are obtained, even though no reflector is provided.

Incidentally, d/p is equal to or less than about 0.5, more preferably equal to or less than about 0.24, in the present preferred embodiment as described above, when the thickness of the piezoelectric layer 2 is d and the center-to-center distance between the electrodes between the electrode 3 and the electrode 4 is p. This will be described with reference to FIG. 33.

A plurality of acoustic wave devices was obtained in the same manner as the acoustic wave device that obtained the resonance characteristics shown in FIG. 32, but d/2p was changed. FIG. 33 is a graph showing a relationship between this d/2p and fractional bandwidth as a resonator of the acoustic wave device.

As is clear from FIG. 33, when d/2p exceeds about 0.25, that is, when d/p > about 0.5, the fractional bandwidth is less than about 5% even when d/p is adjusted. On the other hand, when d/2p ≤ about 0.25, that is, d/p ≤ about 0.5, the fractional bandwidth can be set to be equal to or greater than about 5% by changing d/p within the range, that is, a resonator having a high coupling coefficient can be formed. Further, when d/2p is equal to or less than about 0.12, that is, d/p is equal to or less than about 0.24, the fractional bandwidth can be increased to be equal to or greater than about 7%. In addition, by adjusting d/p within this range, a resonator having an even wider fractional bandwidth can be obtained, and a resonator having an even higher coupling coefficient can be realized. Thus, it can be seen that, by setting d/p to be equal to or less than about 0.5, a resonator having a high coupling coefficient can be provided in which the bulk wave in the thickness shear mode described above is utilized.

Note that, as for the thickness d of the piezoelectric layer, when the piezoelectric layer 2 varies in thickness, a value obtained by averaging thicknesses thereof may be used.

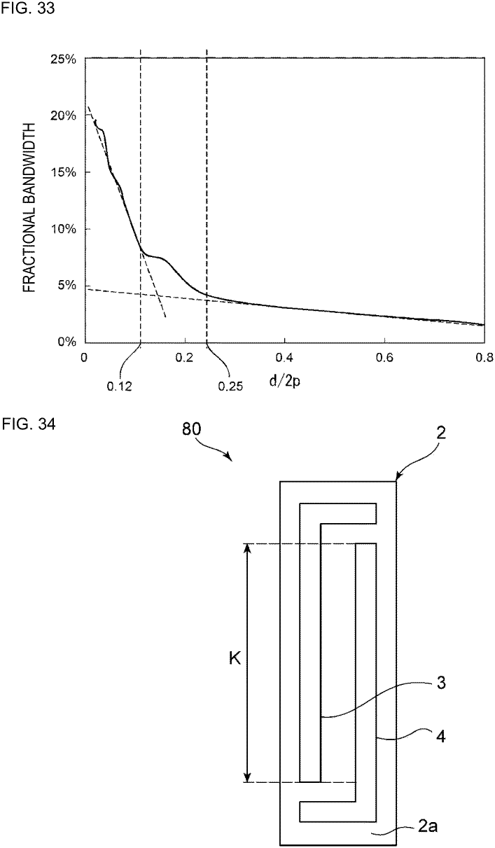

FIG. 34 is a plan view of the acoustic wave device in which the bulk wave in the thickness shear mode is utilized. In an acoustic wave device 80, one pair of the electrodes including the electrodes 3 and 4 are provided on the first main surface 2a of the piezoelectric layer 2. Note that, K in FIG. 34 is an intersecting width. As described above, in an acoustic wave device according to a preferred embodiment of the present invention, the number of pairs of electrodes may be one. Even in this case, when d/p described above is equal to or less than about 0.5, the bulk wave in the thickness shear mode can be effectively excited.

FIG. 35 is a front cross-sectional view of an acoustic wave device having an acoustic multilayer film. In an acoustic wave device 81, an acoustic multilayer film 82 is laminated on the second main surface 2b of the piezoelectric layer 2. The acoustic multilayer film 82 has a laminated structure of low acoustic impedance layers 82a, 82c, and 82e relatively low in acoustic impedance and high acoustic impedance layers 82b and 82d relatively high in acoustic impedance. When the acoustic multilayer film 82 is used, the bulk wave in the thickness shear mode can be confined in the piezoelectric layer 2, without using the air gap 9 in the acoustic wave device 1. Even in the acoustic wave device 81, by setting d/p described above to be equal to or less than about 0.5, resonance characteristics based on the bulk wave in the thickness shear mode can be obtained. Note that, in the acoustic multilayer film 82, the number of laminated layers of the low acoustic impedance layers 82a, 82c, 82e and the high acoustic impedance layers 82b and 82d thereof is not particularly limited. It is sufficient that at least one layer of the high acoustic impedance layers 82b and 82d is disposed on a side farther from the piezoelectric layer 2 than the low acoustic impedance layers 82a, 82c, and 82e.

The low acoustic impedance layers 82a, 82c, 82e and the high acoustic impedance layers 82b and 82d described above can be formed of appropriate materials as long as the above acoustic impedance relationship is satisfied. For example, examples of the material of the low acoustic impedance layers 82a, 82c, and 82e include silicon oxide or polymers, or light metals such as aluminum. Further, examples of the material of the high acoustic impedance layers 82b and 82d include alumina, silicon nitride, tantalum oxide, or heavy metals such as tungsten. However, in the case of the present device using the IDT electrode, an acoustic multilayer film made only of a dielectric film is preferably used, from the viewpoint of causing no parasitic capacitance.

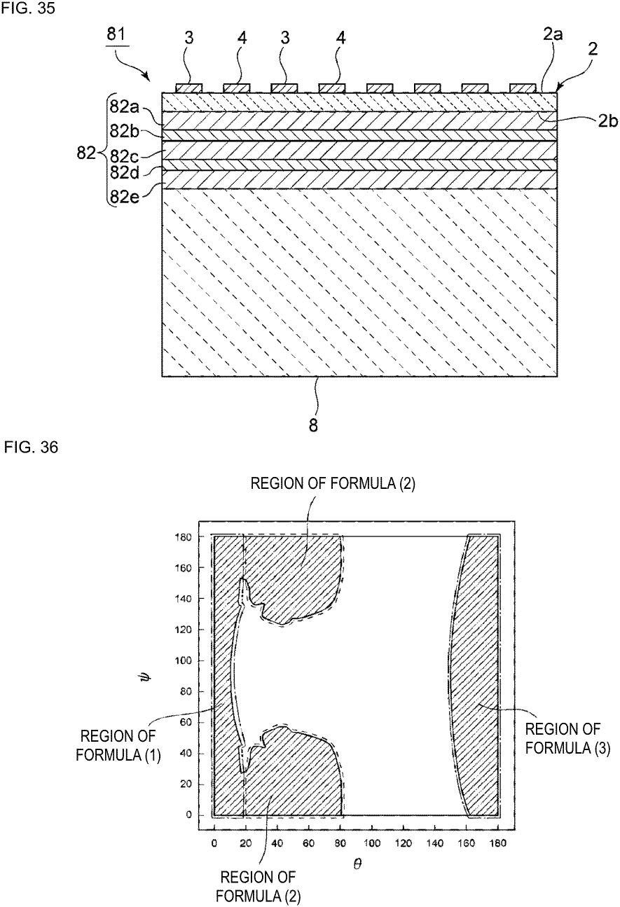

FIG. 36 is a graph showing a map of fractional bandwidth with respect to Euler angles (0°, θ, ψ) of LiNbO₃ when d/p is made as close to 0 as possible. Portions hatched and illustrated in FIG. 36 are regions in which the fractional bandwidth at least equal to or greater than about 5% is obtained, and when ranges of the regions are approximated, ranges represented by the following Formula (1), Formula (2), and Formula (3) are obtained.

(0° ± 10°, 0° to 20°, appropriate ψ) Formula (1)

(0° ± 10°, 20° to 80°, 0° to 60° (1 - (θ - 50)²/900)^{½}) or (0° ± 10°, 20° to 80°, [180° - 60° (1 - (θ - 50)²/900)^{½}] to 180°) Formula (2) Formula (2)

(0° ± 10°, [180° - 30° (1 - (ψ - 90)²/8100)^{½}] to 180°, appropriate ψ) Formula (3) Formula (3)

Thus, in the case of the Euler angle ranges of the above Formula (1), Formula (2) or Formula (3), the fractional bandwidth can be sufficiently widened, which is preferable.

As described above, the acoustic wave devices according to preferred embodiments of the present invention may have the acoustic multilayer film 82 illustrated in FIG. 35. For example, in the first preferred embodiment illustrated in FIG. 2, or the like, the acoustic multilayer film 82 may be provided between the support member 13 and the piezoelectric layer 14.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a piezoelectric layer made of one of lithium niobate and lithium tantalate, and including a main surface;
at least one pair of electrodes on the main surface of the piezoelectric layer; and
a first dielectric film on the main surface of the piezoelectric layer; wherein
a ratio d/p is equal to or less than about 0.5, when a thickness of the piezoelectric layer is d and a center-to-center distance between the electrodes adjacent to each other is p;
the first dielectric film includes a first surface and a second surface facing each other in a thickness direction, the second surface is a surface on a side of the piezoelectric layer;
the at least one pair of electrodes each include a third surface and a fourth surface facing each other in the thickness direction, the fourth surface is a surface on a side of the piezoelectric layer;
the first surface of the first dielectric film is at a same height or higher than the third surface of the at least one pair of electrodes; and
a second dielectric film is on the first surface of the first dielectric film.

2. The acoustic wave device according to claim 1, wherein a projecting portion is in a region overlapping the electrodes in plan view, on a surface of the second dielectric film on a side opposite to a side of the first dielectric film.

3. The acoustic wave device according to claim 2, wherein a thickness of the projecting portion of the second dielectric film is about 0.6 times or less than a thickness of the first dielectric film from the main surface of the piezoelectric layer to the third surface of the electrodes.

4. The acoustic wave device according to claim 3, wherein the thickness of the projecting portion of the second dielectric film is about 0.15 times or less than the thickness of the first dielectric film from the main surface of the piezoelectric layer to the third surface of the electrodes.

5. The acoustic wave device according to claim 1, wherein a density of the first dielectric film is about 0.6 times or greater than a density of the electrodes.

6. The acoustic wave device according to claim 1, wherein a ratio p/d is equal to or greater than 6, when the thickness of the piezoelectric layer is d and the center-to-center distance between the electrodes adjacent to each other is p.

7. The acoustic wave device according to claim 1, wherein
the at least one pair of electrodes include Al; and
the first dielectric film includes at least one material among silicon oxide, silicon nitride, and aluminum nitride.

8. The acoustic wave device according to claim 1, wherein the first dielectric film includes at least one material among tantalum oxide, niobium oxide, and hafnium oxide.

9. The acoustic wave device according to claim 1, further comprising a support directly or indirectly located on a side of the piezoelectric layer opposite to a side on which the at least one pair of electrodes are provided.

10. The acoustic wave device according to claim 9, wherein an air gap that the piezoelectric layer faces is on the side of the piezoelectric layer opposite to the side on which the at least one pair of electrodes are provided.

11. The acoustic wave device according to claim 1, further comprising an acoustic multilayer film laminated on a side of the piezoelectric layer opposite to a side on which the at least one pair of electrodes are provided; wherein
the acoustic multilayer film has a laminated structure of a low acoustic impedance layer relatively low in acoustic impedance and high acoustic impedance layer relatively high in acoustic impedance.

12. The acoustic wave device according to claim 1, wherein
Euler angles (φ, θ, ψ) of lithium niobate or lithium tantalate of the piezoelectric layer are within ranges of a formula (1), formula (2), or formula (3):
(0° ± 10°, 0° to 20°, ψ) Formula (1)
(0° ± 10°, 20° to 80°, 0° to 60° (1 - (θ - 50)²/900)^{½}) or (0° ± 10°, 20° to 80°, [180° - 60° (1 - (θ - 50)²/900)^{½}] to 180°)Formula (2)
(0° ± 10°, [180° - 30° (1 - (ψ - 90)²/8100)^{½}] to 180°, ψ) Formula (3).

13. The acoustic wave device according to claim 1, wherein a bulk wave in a thickness shear primary mode is utilized as a main wave.

14. The acoustic wave device according to claim 1, wherein a thickness of each electrode finger of the at least one pair of electrodes and a thickness of the first dielectric film are the same.

15. The acoustic wave device according to claim 9, wherein the support includes a silicon substrate.

16. The acoustic wave device according to claim 9, wherein the support includes a cavity portion or an air gap.

17. The acoustic wave device according to claim 1, wherein a ratio p/d is equal to or greater than 2, when the thickness of the piezoelectric layer is d and the center-to-center distance between the electrodes adjacent to each other is p.

18. The acoustic wave device according to claim 1, wherein a ratio p/d is equal to or greater than 4, when the thickness of the piezoelectric layer is d and the center-to-center distance between the electrodes adjacent to each other is p.

19. The acoustic wave device according to claim 1, wherein a ratio p/d is equal to or greater than 5, when the thickness of the piezoelectric layer is d and the center-to-center distance between the electrodes adjacent to each other is p.

20. The acoustic wave device according to claim 1, wherein a ratio p/d is equal to or greater than 7, when the thickness of the piezoelectric layer is d and the center-to-center distance between the electrodes adjacent to each other is p.
